(19) United States
(12) Patent Application Publication
(10) Pub. No.: US 2004/0148767 A1
(43) Pub. Date: Aug. 5, 2004

(54) Assembly system and method for assembling components on substrates

(76) Inventors: Mohammad Mehdianpour, Munchen (DE); Ralf Schulz, Munchen (DE)

Correspondence Address: HARNESS, DICKEY & PIERCE, P.L.C., P.O.BOX 8910, RESTON, VA, 20195, US

(21) Appl. No.: 10/478,353

(22) PCT Filed: May 17, 2002
(86) PCT No.: PCT/DE02/01788

(30) Foreign Application Priority Data
May 23, 2001 (DE) 101 25 398.2
May 23, 2001 (DE) 101 25 391.5

(51) Int. Cl. H05K 3/30; B23P 19/00

(52) U.S. Cl. 29/832; 29/742; 29/739

(57) ABSTRACT

An assembly system and a method are for assembling components on substrates. The system includes a transport track and several substrate carriers that can be displaced, for example, perpendicularly to the transport track. The substrate carriers can be loaded with substrates using loading that can be displaced in the direction of transport. Manipulation devices for removing components from feed devices and depositing the components on the substrates are arranged next to the transport track, so that they can be displaced laterally in the direction of transport. The feed devices can be displaced in a substantially perpendicular manner in relation to the direction of transport, in order to align the pick-up point for the respective components along a single pick-up track, parallel to the transport track.

The invention relates to an assembly system and a method for assembling components on substrates, with the substrates being able to be fed on an essentially linear transport track and at least one assembly field being located to the side of the transport track in which the substrates are assembled.

An assembly system of the type mentioned at the start is known for example from international patent application WO 95/19099. This discloses an assembly device with a static X-axis, featuring a bar fixed rigidly to the device chassis, along which one or more cars can be moved. Each of the cars has at least one holder. Below the X-bar of the X-axis are the component feed devices which are arranged in groups. At least 2 Y axes are provided by linear bearings which are rigidly connected to the device chassis. Circuit boards are moved on Y-cars along the Y axes. Since at least 2 Y axes are provided, the non-productive time of the holders during loading and unloading of circuit boards can be greatly reduced.

Two different embodiments of the above-mentioned assembly systems are known from WO 95/19099. With one embodiment feed devices as well as a part of the transport track are arranged along the transport track between the two Y axes. There are strong dependencies here between the X axis, along which the boards are transported, and the two Y axes, along which the boards are moved for assembly at the side of the X axis. If a Y car is moved sideways along a Y axis to the X axis, no circuit boards can be transported along the X axis.

Furthermore with the embodiment with which feed devices are located between the two Y axes, the assembled boards transported along the X axis must be forwarded over the Y cars of the other X axis in the X direction along the X axis. During this time no boards can be assembled by means of the other Y axis.

A further embodiment according to WO 95/19099 makes provision for the two Y axes to be embodied directly after each other in the direction of the X axis. However here too there is no opportunity of transporting a board completed along the one Y axis onwards in the direction of the X axis while a further board is being assembled by means of the other Y axis, since the transport device along the X-axis is interrupted by the Y car of the other Y axis moving out in the Y direction. According to WO 95/19099 there are strong dependencies here between the transport of boards function and the assembly of boards function. For example delays can result here since, after the assembly of a board by means of a Y axis, no new boards can be fed in along the X axis since another board is currently being assembled with the other Y axis and this interrupts the transport device along the X axis.

The object of the invention is to specify an assembly system and a method for assembling components on substrates with which the timing of assembly of the substrates can be independent of the changing of the substrates and can thus ensure higher performance and greater flexibility.

This object is achieved by an assembly system with the features according to claim 1 as well as a method for assembling components on substrates with the features of claim 15. Preferred embodiments of the invention are claimed in the dependent claims.

The assembly system in accordance with the invention according to claim 1 makes possible both parallel assembly of substrates on at least two substrate carriers in a assembly field and also exchange of one of the substrates on one of the substrate carriers while assembly is being undertaken on the other substrate on the other substrate carrier. This allows fast and flexible assembly. Through the loading device in accordance with the invention, which can be moved in the direction of transport, that area at which the transport device located along the transport track is interrupted by the substrate carriers will be bridged for substrate carrier moved sideways to the assembly field. For example a substrate can also be moved past an a assembly field in this way while substrates are being assembled on both substrate carriers. The invention thus decouples the transport (of the substrates) function from the assembly (of the substrates) function. The embodiment according to claim 2 makes it possible to increase performance since it provides for assembly fields on both sides of the transport track. The second assembly field can also be supplied with substrates by means of substrate carriers. Both the substrate carriers assigned to the assembly field and those assigned to the second assembly field feature the same axes of movement. In this case two substrate carriers can be moved along one axis of movement for example. Following on from each other in the direction of transport there are at least two axes of movement of the substrate carriers. The common axes of movement of substrate carriers, for which assembly fields are located on different sides of the transport track in each case, mean that a substrate carrier can also be moved directly from one assembly field into another assembly field, for example to make use of a greater variety of components.

According to one embodiment of the invention it is for example possible to arrange a bar running along above the transport track and to move at least one handling device for assembling the components on the substrates along this bar. For assembly the substrate is moved relative to the handling device in parallel to an assembly level. In this case the movement in one of the two assembly directions of the assembly level is undertaken by the substrate carriers. The movement in the other of the two assembly directions is undertaken by moving the handling device along the bar. This allows very precise tolerances and thereby highly accurate assembly since the handling device can be moved relative to the substrates in each of the two assembly directions along a separately provided guide device in each case.

It is also possible to have a embodiment where the handling device moves at an angle to the bar. For example the handling device can be movable at 45 degrees or 90 degrees to the bar, allowing slight deviations from a desired assembly position to be compensated for in the direction at 45 degrees or 90 degrees to the bar.

It is also possible to provide two or more loading devices which can be moved in the direction of transport along the transport track.

For example if one of the loading devices is located in the direction of transport before the substrate carriers and the other loading device is located in the direction of transport after the substrate carriers. In this case each of the loading devices can for example be used to bridge the interruption of the transport device occurring in the area of the next substrate carrier when these substrate carriers are moved from the transport track to the assembly fields. Two loading devices are also useful for example for passing a substrate on along the transport track when the full complement of substrate carriers has been moved out to the side across the interruption arising as a result of several substrate carriers having been moved out. In this case for example the two loading devices can each be moved half way towards each other in the area of the interruption, so that a substrate can be transferred from one loading device to the other loading device. This guarantees greater flexibility of the assembly system in accordance with the invention. Preferably a plurality of feed devices are arranged along the transport track before and/or after the assembly fields in each case. On the feed devices a component is made available at a pick-up point in each case for feeding to the handling device. The feed devices can be moved at an angle to the transport track in each case. for example the feed devices can be moved at 45 degrees of 90 degrees to the transport track. This allows the positions of the components to be picked up to be corrected at the relevant pick-up points. It is thus not necessary to design the handling device so that it moves in the direction at 45 degrees or 90 degrees to the transport track.

A plurality of feed devices can be located on a common carrier in each case. The carrier can be moved at an angle to the transport track by means of a drive. This means that in addition to or as an alternative to the drive of each feed device, a plurality of feed devices can be moved together at an angle, e.g. at 45 or 90 degrees, to the transport track, to compensate for any positional deviations of the components from prespecified pick-up positions. in accordance with the invention a method for assembling components on substrates is also created. In accordance with the inventive method substrates moved along the transport track are transferred by a load device movable in the direction of transport to one of at least two substrate carriers arranged one after the other in the direction of transport. The substrate carriers can each be moved along an axis at an angle to the transport track to an assembly field arranged to the side of the transport track. For example the substrate carriers can be moved at 90 degrees or 45 degrees to the transport track. At the assembly fields the substrates can be assembled on the substrate carriers by means of handling devices.

After assembly the substrates can be moved by means of the substrate carriers to the loading device or transferred to the latter. From the loading device the substrates are transferred to the transport track so that they can be moved along it. This makes flexible assembly of the substrate carriers possible. In addition it is possible to pass on substrates over the area of the substrate carriers in the direction of transport using the loading device movable in the direction of transport. This means that while assembly is being undertaken on the two substrate carriers, substrates can continue to be transported unimpeded along the transport track. The loading device also makes it possible for a substrate completely assembled on a substrate carrier to be removed from this substrate carrier for forward transport to the transport track as well as for a new substrate to be transferred to this substrate carrier while at the same time another substrate is being assembled on the other substrate carrier, without there being any non-productive time for the handling device.

An embodiment of the inventive method makes it possible to move a plurality of feed devices each separately and at an angle to the transport track. In this case the feed devices are each moved at 90 degrees or 45 degrees to the transport track. The result is that at a pick-up point provided at each of the feed devices at which the component to be fed to the handling device is provided in each case, can be moved into a prespecified position relative to the handling device in each case, so that the component can be taken off the handling device in a prespecified position.

It is also possible to align the pick-up points of the feed devices along an individual pick-up track which runs in parallel to the axis of movement of the handling device. This enables a handling device which can accept a large number of components to greatly speed up the picking up of the components. An optical system can be used for example to record the relevant position of the component at the pick-up points. This system can be accommodated on the handling device or can be moved separately over the pick-up points.

The invention is explained in more detail below with reference to the drawing. The drawing shows:

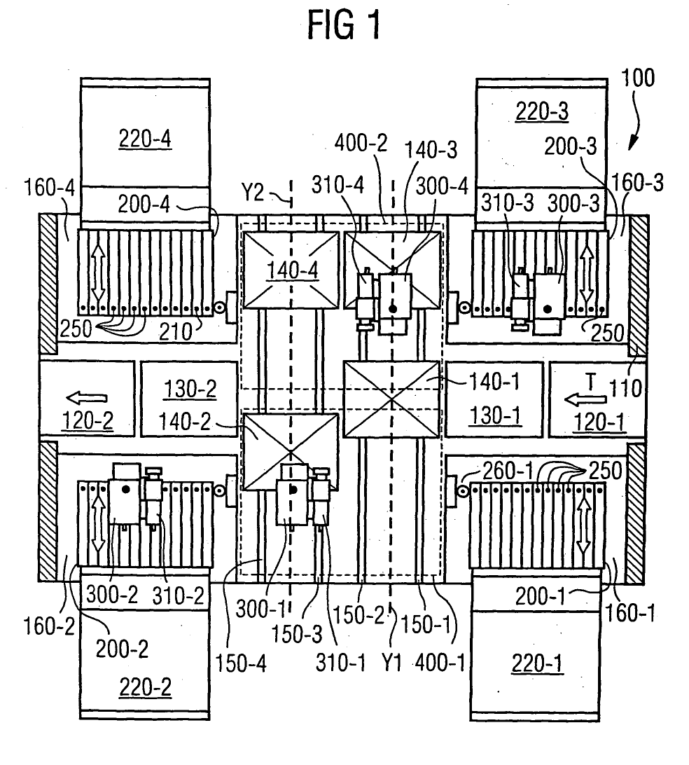

FIG. 1 a schematic view from above of a preferred embodiment of the invention

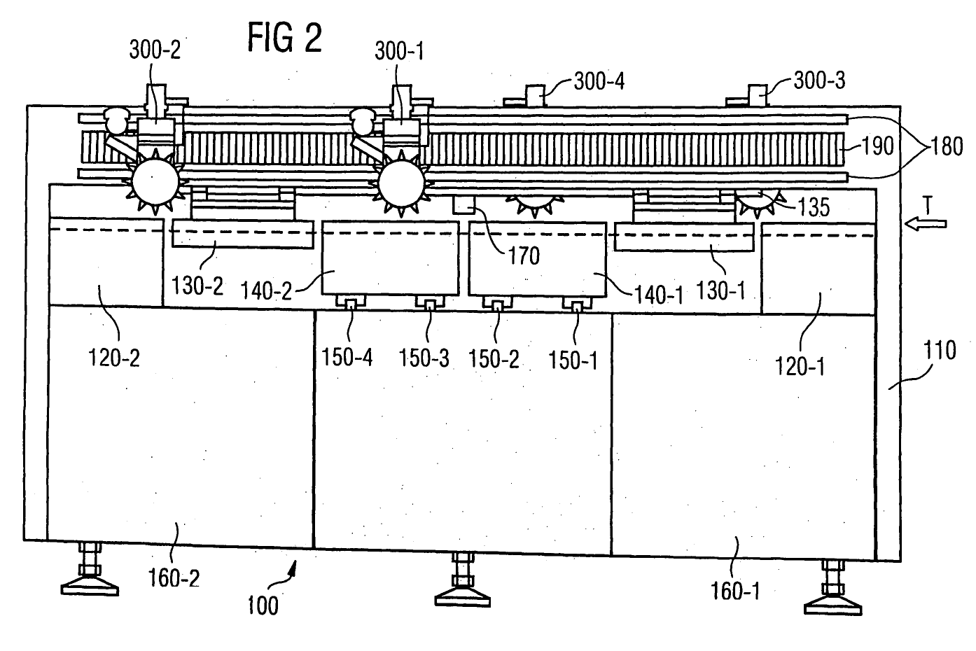

FIG. 2 a schematic side view of the preferred embodiment and

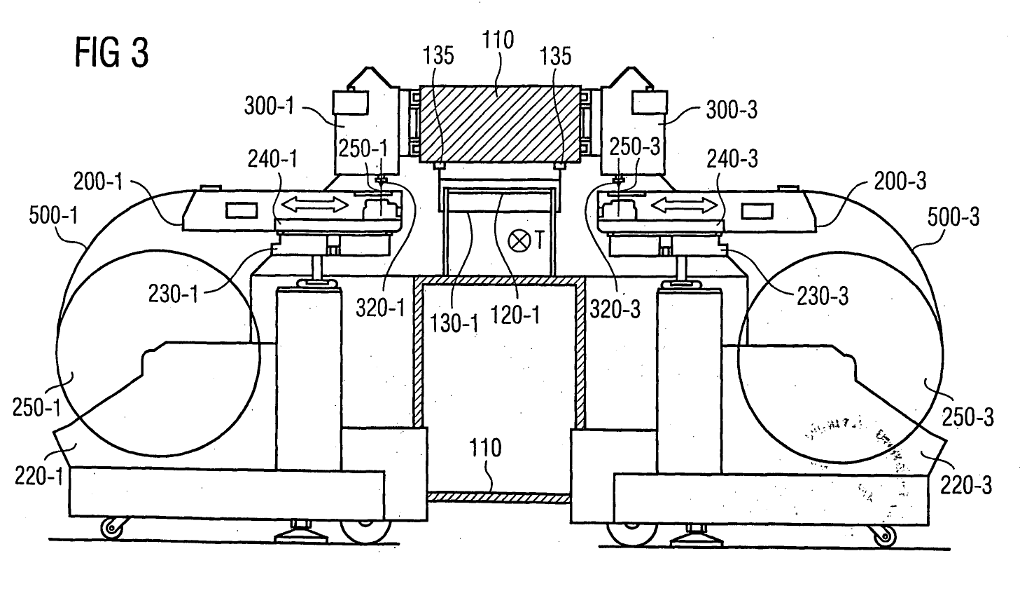

FIG. 3 a schematic front view of the preferred embodiment of the invention.

As can be seen from FIG. 1, a preferred embodiment of the assembly system in accordance with the invention features a chassis 110. A transport track for substrates runs along a direction of transport T through chassis 110. The following units are arranged one after another in the direction of transport T in the assembly system along the transport track: A first transport device 120-1, a first loading device 130-1 which is movable in the direction of transport T, a first substrate carrier 140-1 which can essentially be moved at 90 degrees to the direction of transport T along a first guide device 150-1, 150-2, a second substrate carrier 140-2 which is essentially movable along a second guide device 150-3, 150-4 at 90 degrees to the direction of transport, a third substrate carrier 140-3 which is essentially moved along the first guide device 150-1, 150-2 essentially at 90 degrees to the direction of transport T, a fourth substrate carrier 140-4 which is movable along the second guide device 150-3, 150-4 essentially at 90 degrees to the direction of transport T, a second loading device 130-2 which is movable along the direction of transport T as well as a second transport device 120-2.

The substrates (not shown) are moved along the direction of transport T of the first transport device 120-1 into the assembly system. To this end the first transport device 120-1 is for example equipped with transport belts from which the substrates can be moved in the direction of transport T. The substrates are transferred from the first transport device 120-1 to the first loading device 130-1.

The first loading device 130-1 can also be provided with transport belts for this purpose. FIG. 1 shows the first substrate carrier 140-1 overlaid with the first loading device 130-1. In this position it is possible to transfer substrates from the first loading device 130-1 to the first substrate carrier 140-1. Subsequently the first substrate carrier 140-1 can essentially be moved at 90 degrees to the direction of transport T along the first guide device 150-1, 150-2, so that substrates located on it can be moved to one of the two assembly fields 400-1 or 400-2 along the axis Y1 or Y2 to the side of the transport track where it can be assembled by means of one of the handling devices 300-1, 300-2, 300-3 and/or 300-4.

It is also possible, using the first loading device 130-1 to transfer a substrate to the third substrate carrier 140-3 which can also be moved along the first guide device 150-1, 150-2. Furthermore a substrate can be transferred by means of the first loading device 130-1 to the second substrate carrier 140-2 or to the fourth substrate carrier 140-4 which can be moved along the second guide device 150-3, 150-4 essentially at 90 degrees to the direction of transport T. To transfer or accept the substrates all substrate carriers are provided with conveyor devices, for example with transport belts.

The substrates transferred to the substrate carriers can be moved from these to the first assembly field 400-1 or to the second assembly field 400-2. There they are assembled with components. The components are each made available by a plurality of feed devices 200-1, 200-2, 200-3 and 200-4 at the relevant pick-up points 250.

Each of the plurality 200-1, 200-2, 200-3 and 200-4 of feed devices features a pick-up point 250. Each of the plurality of feed devices 200-1, 200-2, 200-3, 200-4 forms a feed module.

The components made available at the pick-up points 250 are picked up by the handling devices 300-1, 300-2, 300-3 and 300-4, for example revolver assembly heads, and set down at the prespecified positions on the substrates. For this purpose the handling device can be moved along a bar (not shown) parallel to the transport track. To guarantee a secure pick-up of the components at the pick-up points 250 it is necessary to arrange all pick-up points 250 of a feed module along one pick-up track in each case which runs in parallel to the transport track.

The components are however held in magazines and have storage tolerances within the magazine. It can thus be necessary to essentially move the feed devices individually in each case at 90 degrees to the direction of transport T to enable all components to be fetched to be arranged along the pick-up track. For this purpose all feed devices are each provided with a drive.

To enable storage deviations of the components at the pick-up points 250 to be detected the handling devices 300-1, 300-2, 300-3 and 300-4 are each provided with an optical measurement system, for example a camera 310-1, 310-2, 310-3 or 310-4. by passing the handling device over the relevant pick-up track of a feed module the positional tolerances of the relevant components at the pick-up point 250 can be determined and subsequently by controlling the relevant drives of the feed devices all components can be aligned along a single pick-up track.

The feed modules 200-1, 200-2, 200-3 and 200-4 are each positioned in a compartment 160-1, 160-2, 160-3 or 160-4 of the chassis 110 of the assembly system. In the relevant compartment or on the feed module there can further be provision for an optical measurement device 260-1, 260-2, 260-3 or 260-4. With this optical measurement device 260-1, 260-2, 260-3 and 260-4 it is possible in each case to determine the position of a component picked up by a handling device relative to the handling device. Thus it is for example possible to allow imprecision in the picking up of components, since the position of the component relative to the handling device is subsequently detected. Because of the known deviation the placement position of the handling device on the substrate can be corrected by the positional deviation of the component relative to the handling device so that the component can be placed at exactly the prespecified point on the substrate.

FIG. 2 shows a schematic side view of the preferred embodiment of the invention. In addition to the details that can be seen from FIG. 1, the figure shows a guide bar 180 on which the handling device 300-1 and 300-2 are guided. The guide bar 180 is in this case located on one side of the chassis which faces the first assembly field 400-1. On the opposite side of the chassis is a further guide bar (not shown) is located in a similar way, on which the handling devices 300-3 and 300-4 which are assigned to the second assembly field 400-2 are arranged.

A primary or secondary part of a linear motor is located on the handling devices in each case. The corresponding secondary or primary part 190 is arranged on the guide bars 180 in each case.

This allows the handling devices to be moved quickly and highly precisely along the guide bar 180. it can further be seen from FIG. 2 that the loading devices 130-1 and 130-2 are each guided along a guide bar 135 in the direction of transport T which runs along the transport track above the transport level. An optical measurement system 170 is further accommodated on the guidance bars 135 and this can be moved by means of a drive along the guidance bars 135 in the direction of transport By means of the optical measurement system 170 it is possible to detect the position of the substrate relative to the substrate carriers 140-1, 140-2, 140-3 and 140-4. This information is fed into a central control device of the assembly system. FIG. 3 shows a schematic front view of the assembly system in accordance with the preferred embodiment of the invention. In addition to the elements shown in FIGS. 1 and 2, it can be seen from FIG. 3 that the handling device 300-1 and 300-3 are each equipped with a component holder system 320-1 or 320-3. The component holder system can for example be a vacuum pipette. However another gripper can also be used.

Further it can be seen from FIG. 3 that the feed devices 200-1 and 200-3 are fed with a magazine 500-1 or 500-3, each of which is loaded with components. In particular the magazines 500-1 and 500-3 on belt ribbons 250-1 or 250-3 are threaded component belts. The feed devices 200-1 and 200-3 are each attached to a support block 230-1 or 230-3 so that release is possible. Each feed device 200-1 and 200-3 features a drive 240-1 or 240-3 by means of which the feed device 200-1 or 200-3 can essentially be moved at 90 degrees to the direction of transport T, to enable any possible deviations in position of the components at the pick-up points 250-1 and 250-3 to be compensated for.

The handling devices 300-2 and 300-4 and feed devices 200-2 not visible in FIG. 3 behind the drawing level are of the same design as the handling device 300-3, or the feed devices 200-1 and 200-3 described.

With the inventive assembly system each handling device 300-1, 300-2, 300-3 and 300-4 is basically uniquely assigned to one of the plurality of feed devices 200-1, 200-2, 200-3 or 200-4. It is however also possible with both handling devices 300-1, 300-2, or 300-3, 300-4 arranged on a guide bar to access all feed devices on one side of the guide bar in each case, to increase the variety of components available to a handling device.

Since the position of the components on the handling devices is checked by an optical measurement system after the component is picked up, it is possible to accept components with less precision and despite this to be able to place them with greater accuracy on the substrates.

1. assembly system for assembling substrates with components, in which the substrates can be fed on an essentially linear transport track, along which the substrates are essentially moved in a direction of transport (t), and in which to the side of the transport track at least one feed device (200-1, 200-2) for feeding components as well as at least one assembly field (400-1) are arranged in which the substrates are assembled, with the assembly field (400-1) is assigned a handling device (300-1, 300-2) for assembling the fed components at prespecified assembly positions on the substrates and in which a transport device (120-1, 120-2) is located along the transport track for moving the substrates which is interrupted in the area of the assembly field of substrate carriers characterized in that
there is provision, in the direction of transport (t) for at least two substrate carriers (140-1, 140-2) arranged one after the other in the area of the assembly field (400-1),
The substrate carriers (140-1, 140-2) can each be moved along an axis of movement (Y1, Y2) at an angle to the transport track between an area of the transport track and the assembly field (400-1) arranged to the side of the transport track,
in the direction of transport (t) before and/or after the substrate carriers (140-1, 140-2) there is provision for at least one loading device (130-1) movable in the direction of transport (t), from which substrates can be transferred between the transport track and the substrate carriers(140-1, 140-2), and
the substrate carriers (140-1, 140-2) and the loading device (130-1) feature a common area of movement along the transport track, and the transport device (120-1, 120-2) is interrupted in this common area of movement by the substrate carriers (140-1, 140-2) and the loading device (130-1).

2. Assembly system according to claim 1,
characterized in that
at least one second assembly field (400-2) is provided, which is arranged opposite the assembly field (400-1) in relation to the transport track,
two additional substrate carriers (140-3, 140-4) are provided, similar to the two substrate carriers (140-1, 140-2) which are assigned to the second assembly field (400-2)
the axes of movement (Y1, Y2) of the substrate carriers (140-1, 140-2) correspond to the axes of movement (Y1, Y2) of the additional substrate carriers (140-3, 140-4) with the substrate carriers (140-1, 140-2) the additional substrate carriers (140-3, 140-4) and the loading device having a common area of movement along the transport track.

3. Assembly system according to claim 1 or 2,
characterized in that
there is a bar (180) to the side along each side of the transport track equipped with substrate carriers (140-1, 140-2, 140-3, 140-4) arranged above the transport track,
The bar (180) is arranged in the area of the substrate carriers (140-1, 140-2, 140-3, 140-4), and
at least one handling device (300-1, 300-2, 300-3, 300-4) is guided so that it can be moved along the bar (180) to assemble the components on the substrates.

4. Assembly system according to claim 2 or 3,
characterized in that
each bar (180) is provided with two handling devices (300-1, 300-2, 300-3, 300-4).

5. Assembly system according to claim 2 to 4,
characterized in that
to assemble the substrates, the handling device (300-1, 300-2, 300-3, 300-4) is movable in two directions of an assembly level essentially parallel relative to the surface of the substrate to be assembled,
The movement can be undertaken in one of the two assembly directions by means of the substrate carriers (140-1, 140-2, 140-3, 140-4), and
The movement in the other assembly direction can be undertaken by means of the handling device (300-1, 300-2, 300-2, 300-4) arranged on the bar (180).

6. Assembly system according to claim 2 to 5,
characterized in that
The handling device (300-1, 300-2, 300-3, 300-4) can be moved at an angle to the bar (180).

7. Assembly system according to one of the previous claims,
characterized in that,
two loading device (130-1, 130-2) are provided, with one of the loading devices (130-1) being located in the direction of transport (T) before the substrate carriers (140-1, 140-2, 140-3, 140-4) and the other loading device (130-2) being located in the direction of transport after the substrate carriers (140-1, 140-2, 140-3, 140-4),

8. Assembly system according to one of the previous claims, characterized in that each loading device (130-1, 130-2) is supported above the transport track.

9. Assembly system according to one of the previous claims,
characterized in that,
a plurality of feed devices (200-1, 200-2, 200-3, 200-4) are located along the transport track before and/or after the assembly fields (400-1, 400-2),
The feed devices (200-1, 200-2, 200-3, 200-4) each feature a pick-up point at which the components to be fed to the handling device (300-1, 300-2, 300-3, 300-4) can be made available in each case,
The feed devices (200-1, 200-2, 200-3, 200-4) can be moved at an angle to the transport track.

10. Assembly system according to claim 9,
characterized in that
The feed devices (200-1, 200-2, 200-3, 200-4) are each equipped with a drive (240-1, 240-2, 240-3, 240-4) from which they can be moved at an angle to the transport track

11. Assembly system according to claim 9 or 10,
characterized in that
a plurality of feed devices (200-1, 200-2, 200-3, 200-4) is arranged on a carrier in each case, and
The carrier can be moved by means of a drive at an angle to the transport track.

12. Assembly system according to one of the previous claims.,
characterized in that
a plurality of assembly fields (400-1, 400-2) are arranged on both sides of the transport track,
substrates can be moved from a first assembly field (400-1) by means of the substrate carriers (140-1, 140-2, 140-3, 140-4) or by means of the substrate carriers (140-1, 140-2, 140-3, 140-4) and the loading device (130-2) or by means of the substrate carriers (140-1, 140-2, 140-3, 140-4) and the second loading device (130-2) across the transport track to a second assembly field (400-2).

13. Assembly system according to claim 12, characterized in that
The first assembly field and the second assembly field are arranged diagonally to each other with regard to the transport track.

14. Method for assembling substrates with components, with the substrates being able to be fed on an essentially linear transport track, along which the substrates are moved essentially in a direction of transport (T), and in which to the side of the transport track at least one feed devices (200-1, 200-2, 200-3, 200-4) to feed components as well as at least one assembly field (400-1, 400-2) are arranged, in which the substrates are assembled, with a handling device (300-1, 300-2, 300-3, 300-4) for assembling the fed components at prespecified assembly positions on the substrates is assigned to the assembly field (400-1, 400-2) and with a transport device (120-1, 120-2) being arranged along the transport track to move the substrates which is interrupted by substrate carriers in the area of the assembly field (400-1, 400-2) characterized in that
the substrates moved along the transport track are fed to a loading device (130-1) movable in the direction of transport (T),
the substrates are moved from the loading device (130-1) to one of at least two substrate carriers (140-1, 140-2) arranged one after the other in the direction of transport (T) and are transferred to the latter,
the substrates are moved by the substrate carriers (140-1, 140-2) in each case along a axis of movement (Y1 Y2) at an angle to the transport track to the assembly field (400-1, 400-2) arranged at the side of the transport track, The substrates are assembled on the substrate carriers (140-1, 140-2) at the assembly fields by means of the handling devices (300-1, 300-2, 300-3, 300-4),
the substrates are moved by means of the substrate carriers (140-1, 140-2) to the loading device (130-1) and transferred to this, and
the substrates are transferred by means of the loading device (130-1) to be moved along the transport track.

15. Method according to claim 14, with a plurality of feed devices (200-1, 200-2, 200-3, 200-4) being assigned to an assembly field (400-1, 400-2), which each feature a pick-up point (250) at which the components to be fed to the handling device ((300-1, 300-2, 300-2, 300-4) are made available,
characterized in that
deviations from a specified position of the component relative to the pick-up point (250) are detected, and
if deviations have been detected, the feed devices (200-1, 200-3, 200-3, 200-4) are each moved at an angle to the transport track to compensate for the deviations before a component is picked up.

16. Method according to claim 15,
characterized in that
the pick-up points (250) of the feed devices (200-1, 200-2, 200-3, 200-4) are arranged along a pick-up track which runs in parallel to the axis of movement of the handling device (300-1, 300-2, 300-3, 300-4).

17. Method according to claim 15 or 16,
characterized in that
the detection is undertaken by means of an optical system (310-1, 310-2, 310-3, 310-4), which is accommodated on the handling device (300-1, 300-2, 300-3, 300-4).

18. Method according to claim 14 to 17,
characterized in that
the substrate carriers (140-1, 140-2) are each moved alternately between the assembly field (400-1, 400-2) and the transport track, and
while a substrate that is located on one substrate carrier (140-1, 140-2) is being assembled by means of the handling device (300-1, 300-2, 300-3, 300-4) in the assembly field (400-1, 400-2) on another substrate carrier (140-1, 140-2) another substrate is positioned in the area of the transport track, calibrated, removed and/or moved between the assembly field and transport track and/or moved by means of the loading device (130-1) along the transport track past the assembly field (400-1, 400-2).
